(19) United States
(12) Patent Application Publication
(10) Pub. No.: US 2019/0104618 A1
(43) Pub. Date: Apr. 4, 2019

(54) METHOD FOR SOLVENT-FREE PRINTING CONDUCTORS ON SUBSTRATE

(71) Applicants: Jun YANG, Guangdong (CN); Tengyuan ZHANG, Shandong (CN); Qiuquan GUO, Guangdong (CN)

(72) Inventors: Jun YANG, Guangdong (CN); Tengyuan ZHANG, Shandong (CN); Qiuquan GUO, Guangdong (CN)

(21) Appl. No.: 16/086,851

(22) PCT Filed: Mar. 7, 2017
(86) PCT No.: PCT/CN2017/075849

§ 371 Date: Sep. 20, 2018

Related U.S. Application Data
(60) Provisional application No. 62/311,872, filed on Mar. 22, 2016.

(51) Int. Cl. H05K 3/10; G03G 9/093; H05K 3/12; C08J 3/20

(52) U.S. Cl. CPC H05K 3/106; G03G 9/093; H05K 2203/0502; C08J 3/20; H05K 3/1266

(57) ABSTRACT

A solvent-free method for fabricating conductors is disclosed. A thick patterned layer up to 13 microns containing metal precursor and reducing agent precursor are initially deposited onto a substrate using laser printing technology. The deposited patterned precursor materials are then irradiated with a newly developed high energy intense pulsed light (IPL) system in order to transform the deposited materials to thick conductive metal patterns. The easy metallization of printed patterns makes this invention an especially effective method for massive production of flexible printed circuits.

### BACKGROUND OF THE INVENTION

### 1. Technical Field

The disclosed invention relates to printed electronics in general, and, in particular, to a solvent-free method of fabricating thick conductive patterns on a substrate.

### 2. Background

Printed electronics, flexible electronics and wearable electronics, with the potential of reforming the electronics industry and changing our daily life, constitute a rapidly growing area of research. Various printing techniques, such as inkjet printing, gravure printing, screen printing, aerosol-jet printing and laser-induced forward transfer printing (LIFT), have been adopted to fabricate electrical and electronic devices for a broad variety of applications. High-efficiency and scalable printing techniques are always appealing to printed electronics community. R&D of printed electronics have been significantly advanced these years. Most of the existing printed electronics techniques are solution based methods, involving solvent(s). Usually, solution processable electrically active and/or special functional materials, such as metal nanoparticles, carbon nanotubes, conductive/functional polymers, or ion gel are formulated into different inks for printing. Metal nanoparticles like Ag nanoparticles have been widely explored as conductive inks, playing a major role in printed electronics. However, for the existing conductive inks composed of small metal nanoparticles, large amounts of stabilizing, capping and/or modified agent(s) are required in order to prevent the nanoparticles from aggregation, precipitation and oxidization, resulting in a low solid loading and high impurity content, and consequently, causing a high electrical resistance of the printed patterns. Though many efficient sintering methods such as selective laser sintering, pulsed light sintering, plasma and microwave flash sintering have been employed to anneal the printed patterns and yield an improved conductivity up to 60% of the bulk materials, the resistance of these printed conductive traces are still high due to the thin (<1 μm) conductive layer, making the printed electrodes hard to fulfill the requirements of the electronics industry. In addition, the preparation of high-quality ink is usually complicated and costly. In terms of ink formulation, it often has strict requirements for viscosity and surface tension. The printing quality can be easily affected by the intrinsic limitation, like pinhole formation, and the adhesion of the ink to the substrate is also a common challenge for all wet processing techniques.

Recently, several printing techniques, including inkjet printing, nanoimprinting and screen printing, have emerged as a very promising technical trend to produce flexible and stretchable electronics/devices. Especially for the material or inkjet printing as an additive manufacturing method, it has proved to be very versatile and cost-effective for making flexible and stretchable electronics via a direct writing manner with merits of high efficiency, low material consumption and programmable control. However, challenges remain in low conductivity of printed circuits, weak adhesion between the printed materials and the substrates, low resolution, limited choices of substrate materials, and relatively high cost due to the use of Ag or Au nanoparticle based conductive inks. Particularly the low conductivity and weak adhesion problems directly affect the quality control during the manufacturing, and performance and lifetime of the devices during the use. If the printing resolution can be improved, cost and material consumption will be reduced, throughput will be further increased, and many more applications will become available.

### 3. Description of Related Art

Photonic curing is the power intensive processing of a material using high energy light pulses from a flashlamp, usually xenon lamp. Photonic curing allows materials on low-temperature substrates to be processed in much shorter time periods (about 1 millisecond) than with an oven (which takes up to hours) without causing damage to thermal sensitive substrates. The intense pulsed light can decompose thermoplastic non-transparent or other non-transparent polymer materials to alcohol and acid in gas phase, and also provide the energy of reducing metal precursor in the alcohol and acid environment.

Laser printing is a solvent-free, high-speed, and electrostatic digital printing process that rapidly produces high quality patterns by passing a laser beam over a charged drum in order to define a differentially charged image and has been widely used in our daily life. Although laser printing has been widely utilized in graphic printings, using laser printing for device fabrication is rarely reported except few cases such as laser-induced forward transfer printing, laser printed pattern for controlling the growth of carbon nanotube and fabricating microfluidic devices. Laser printing is advantageous as there are no required solvents and so it unnecessary to worry about the solubility of the metal and toner powders. Unlike inkjet printing, laser-printing uses dry toner powder, so there is no constraint on viscosity and surface tension. Since the introduction of the laser printer, they have become more affordable, allowing them to become viable options in both printed electronics and personal use. Laser-induced forward transfer (LIFT) is a technique that propels the laser to the substrate without a phase change allows for deposition of complex materials without degradation of properties. Using the LIFT technique, Ag patterns with smooth and uniform profiles can be transferred with high precision, while circular and uniform droplets can be obtained with high reproducibility.

Alcohol and acid reduction mechanisms have been widely used for synthesis metal by reducing metal oxide¹⁻³. The following equations (1-6) shows the mechanism and the favorable thermodynamics of these reactions.⁴ ¹ Ming-Shin Yeh, Yuh-Sheng Yang, Yi-Pei Lee, Hsiu-Fang Lee, Ya-Huey Yeh, and Chen-Sheng Yeh, The Journal of Physical Chemistry B 103 (33), 6851 (1999).² Jaehoon Lee, Dong-Kuk Kim, and Weekyung Kang, Bulletin of the Korean Chemical Society 27 (11), 1869 (2006).³ Harveth Gil, Alejandro Echavarria, and Felix Echeverría, Electrochimica Acta 54 (20), 4676 (2009).⁴ P J Soininen, K-E Elers, V Saanila, S Kaipio, T Sajavaara, and S Haukka, Journal of The Electrochemical Society 152 (2), G122 (2005).

Cu₂O+CH₃OH(g)→2Cu+H₂O(g)+HCHO(g) G(310° C.)=−69 kJ (1)

Cu₂O+C₂H₅OH(g)→2Cu+H₂O(g)++CH₃CHO(g) G(310° C.)=−87 kJ (2)

Cu₂O+PrⁱOH(g)→2Cu+H₂O(g)+(CH3)₂CO(g) G(310° C.)=−102 kJ (3)

Cu₂O+C₃H₇CHO(g)→2Cu+C₃H₇COOH(g) G(310° C.)=−86 kJ (4)

Cu₂O+¼CH₃COOH(g)→2Cu+½H₂O(g) G(310° C.)=−99 kJ (5)

Cu₂O+HCOOH(g)→2Cu+H₂O(g)+CO₂(g) G(310° C.)=−161 kJ (6)

### SUMMARY OF THE INVENTION

In accordance with a preferred embodiment of the present invention, metal precursor and reductant precursor materials are synthesized. The synthesized materials are laser printable. Patterns are initially deposited onto a substrate such that the substrate can be flexible, rigid, organic or inorganic. The patterned precursor material is then irradiated with a newly developed high energy intense light pulse in order to transform the precursor materials to thick pure metal patterns such that the patterns are electrically conductive. All features and advantages of the present invention will become apparent in the following detailed written description.

### DETAILED DESCRIPTION OF THE INVENTION

The present disclosure is directed to the preparation of a novel toner, printing and post-treatment of as-printed patterns. The reductant/metal precursors are incorporated into regular toner to form novel toner that enables the further functionalization of printed patterns. Several typical thermoplastic polymer and other polymers which are rich of alcohol and acid groups are selected as the reductant precursor. Metal precursors can be, but not limited to, metal complex, metal salt, metal oxide, metal crystal, metal hydroxides. The metal elements can be silver, gold, copper, nickel, platinum, indium, tin, gallium and any other possible elements that are electrically conductive. These reductant precursors have common features, and they can be decomposed to alcohol and acid under the high power pulsed light.

In this disclosure, above-mentioned reductant precursor and metal precursor are mixed with regular toner. The regular toner is either synthesized by emulsion polymerization method, or is directly purchased from the market. Reductant and/or metal precursors are also obtained from commercial markets or are synthesized by chemical methods. After preparing toner and reductant/metal precursors, generally there are two approaches to mix them in this disclosure, liquid phase mixing and solid state blending. In liquid-phase mixing, catalysts are dissolved in the solvent firstly, such as deionized water, and the toners are dispersed in the same solvent with the assistance of surfactants. Then the reductant precursor solution or metal salt solution is slowly dropped into the toner dispersion under stirring to achieve good mixed effects. However, due to the influence of solvent, liquid phase mixing may change the initial properties of toner particles more. Naturally, solid state blending has been a good choice to prepare the novel toner. Solid state blending mainly involves ball milling, mechanical grinding, blast mixing, stirring, etc.

In this disclosure, reductant precursors or metal precursors are firstly pulverized into fine powders, less than 10 microns. Then fine as-prepared powders are mixed with toner particles. Typically, in this process, planetary ball milling is employed for the pulverization of reductant/metal precursors particles and the mixing of precursor materials and toner particles. The rotation of planetary ball milling is usually required to stay in a low speed to prevent dramatic rising of temperature. Too high temperature may fuse the toner together and affect the subsequent printing quality.

In this disclosure, the as-prepared precursor functional toners are deposited onto a substrate using laser printing. The printing quality of the reductant/metal precursors containing toners is in relation to the homogeneity of the mixture and the loading content of precursor materials. Homogeneous mixing of catalyst is beneficial for the improvement of printed quality. The printing quality is also affected by the properties of printed substrates. High surface energy can help the adhesion of other substance on the surface. Surface energy relates to surface area and surface tension. Obviously, large roughness and high surface tension are beneficial for enhanced adhesion stability. Thus, the printing substrates are required to have large roughness and surface tension. Some surface modifications to increase the surface roughness and surface tension are useful for improving the printing quality. For laser printing, the toner particles are usually melted into the substrate. The interaction between toner and substrate is non-covalence force, and thus in order to improve the adhesion force it is an effective method to increase the number of hydrogen bonds. The introduction of hydroxide group, carboxyl group, and carbonyl group into the substrate will help to improve the surface adhesion.

In this disclosure, the printed reductant/metal precursors patterns are irradiated with a high power intense pulsed light in order to transform precursor materials to pure conductive metal patterns. During the irradiation with light pulses, the reductant precursor is decomposed into alcohol and acid in gas phase creating a partial reducing environment. At the same time, the pulsed light provides the energy needed for the alcohol/acid reduction of metal precursors, yielding pure metal, water (gas) and carbon oxide. The printed patterns will become highly conductive after development. To achieve a uniform metallization of the precursor materials, a rapid high power pulse train which is synchronized to moving substrate is adopted.

1. A solvent-free method for fabricating printed electronics onto a substrate, said method comprising:
I. Synthesizing reductant precursor and metal precursor containing laser printable toners.
II. Depositing the precursor containing toners onto a substrate.
III. Irritating said deposited precursor patterns with a high energy intense pulsed light to transform the said deposited precursor patterns to electrically conductive patterns.

2. The method of claim 1, wherein said depositing is performed by laser printing.

3. The method of claim 1, wherein said substrate is paper, PET, PI, PEI, FR-4, SEI.

4. The method of claim 1, wherein said the metal precursor material included a particulate metal.

5. The method of claim 4, wherein said metal precursor can be metal oxide, metal complex, metal salt, metal polymer compound, metal nanoparticles with capping agent.

6. The method of claim 4, wherein said particulate metal is a metal selected from the group consisting of copper, nickel, silver, cobalt gold, platinum, palladium and combinations thereof.

7. The method of claim 1, wherein said reductant precursor included a particulate polymer which decomposed to alcohol and acid under high energy pulsed light.

8. The method of claim 6, wherein said particulate polymer selected from group consisting of polyesters, styrene butadiene copolymers, styrene acrylate copolymers, polyvinylpyrrolidone, polyvinyl alcohol and combinations thereof.

9. The method of claim 1, wherein said reductant precursor has a concentration range from 0.1 wt % to 90 wt %.

10. The method of claim 1, wherein said metal precursor has a concentration range from 10 wt % to 90 wt %.
